(19) United States
(12) Patent Application Publication
(10) Pub. No.: US 2025/0201751 A1
(43) Pub. Date: Jun. 19, 2025

(54) IC DEVICE WITH CHIP TO PACKAGE INTERCONNECTS FROM A COPPER METAL INTERCONNECT LEVEL

(71) Applicant: Texas Instruments Incorporated, Dallas, TX (US)

(72) Inventor: Manoj Kumar Jain, Plano, TX (US)

(21) Appl. No.: 19/064,073

(22) Filed: Feb. 26, 2025

Related U.S. Application Data
(63) Continuation of application No. 17/331,921, filed on May 27, 2021, now Pat. No. 12,261,141.

(51) Int. Cl. H01L 23/00; H01L 21/56; H01L 21/768; H01L 23/532

(52) U.S. Cl. CPC H01L 24/20; H01L 21/565; H01L 21/76877; H01L 23/53228; H01L 24/11; H01L 24/13; H01L 24/19; H01L 24/82; H01L 24/94; H01L 2224/13147; H01L 2224/13655; H01L 2224/13664; H01L 2224/14505; H01L 2224/2101; H01L 2224/215

(57) ABSTRACT

An integrated circuit device (100) and method comprising an IC chip (102) having metal interconnect levels (M1-Mn) including a last copper interconnect level (Mn) and a chip-to-package interconnect (110) overlying and connected to the last copper interconnect level (Mn). The chip-to-package interconnect (110) having a via (112) connected to a first element (306a) of the last copper interconnect level (Mn) and a copper conductive structure (118) (e.g., bump copper). The via (112) includes a barrier material (112a) and a tungsten fill layer (112b), the via coupled between the copper conductive structure (118) and the first element (306a).

### CROSS-REFERENCE TO RELATED APPLICATIONS

This application is a Continuation of U.S. patent application Ser. No. 17/331,921, filed on May 27, 2021, which claims priority to U.S. Provisional Application No. 63/033,247, filed Jun. 2, 2020, which are incorporated herein by reference in their entirety.

### FIELD OF THE INVENTION

The invention is generally related to the field of integrated circuit devices and more specifically to integrated circuit devices having copper interconnect levels.

### BACKGROUND OF THE INVENTION

Integrated circuits are formed on chips or die of a semiconductor wafer, such as silicon. Each integrated circuit chip typically includes multiple aluminum interconnect levels to interconnect elements of the integrated circuit with each other and provide connections external to the chip. The chips are then assembly packaged using one of a number of different packaging techniques. In order to package the chip, chip-to-package interconnects are formed that vary depending on the packaging technique used. Chip-to-package interconnects can include wire-bonds, solder bumps, copper pillar, and others. The chip-to-package interconnects connect the top or last metal interconnect level of the chip to, for example, another IC chip or device within the same package or an external pin (such as through a lead frame).

### SUMMARY OF THE INVENTION

An integrated circuit device and method comprising an IC chip having metal interconnect levels (M1-Mn) including a last copper interconnect level Mn and a chip-to-package interconnect overlying and connected to the last copper interconnect level Mn. The chip-to-package interconnect having a via connected to a first element of the last copper interconnect level Mn and a copper conductive structure (e.g., bump copper). The via includes a barrier material and a tungsten fill layer, the via coupled between the copper conductive structure and the first element.

### BRIEF DESCRIPTION OF THE DRAWINGS

In the drawings:

FIG. 1 is a flow diagram of a wafer fab to assembly-packaging of an IC device.

FIG. 2 is a cross-sectional diagram of an IC chip to IC device according to an embodiment.

FIG. 3A-3F are cross-sectional diagrams of an IC device at various stages of IC manufacturing according to an embodiment.

FIG. 4-9 are cross-sectional diagrams of IC devices according to various embodiments.

### DETAILED DESCRIPTION OF THE EMBODIMENTS

The embodiments will now be described in conjunction with chip-to-package interconnects for an integrated circuit device having a top/last interconnect level formed by a damascene copper process. While especially beneficial for analog power devices with increased current density requirements, the embodiments below are also suitable for other devices such as low power digital devices (sometimes referred to as advanced CMOS).

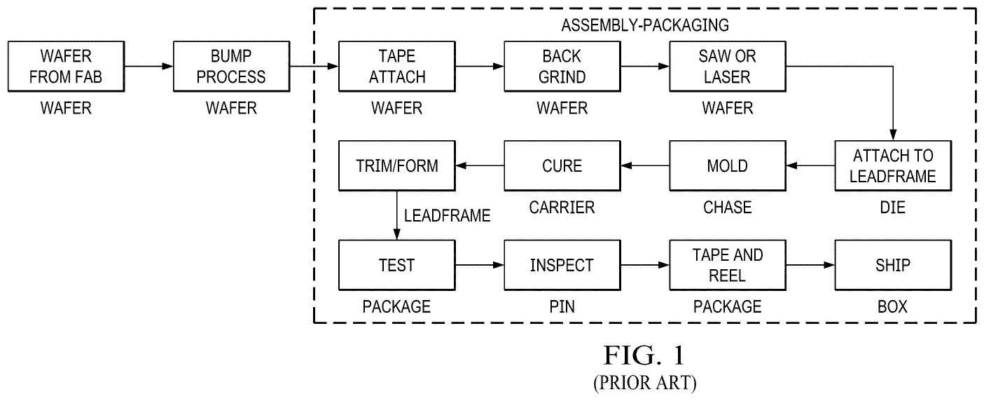

As used herein, integrated circuit device (IC device) refers to an integrated circuit chip that has been assembly-packaged. One exemplary process is shown in FIG. 1. Once an integrated circuit chip is fabricated on a semiconductor wafer in a semiconductor fabrication facility (Fab), Bump processing may be performed, and then the wafer may be transferred to an Assembly-Test site for assembly-packaging. In some cases, one site may contain both the bump operations and assembly-packaging or both the Fab and bump operations. Typical assembly-packaging steps include backgrind, singulation (laser or mechanical saw), attach to lead frame, mold, trim/form of the leads from the lead frame, and test before shipping. Other suitable assembly-packaging processes, such as wafer chip scale packaging, are known in the art and may alternatively be used with the chip-to-package interconnect embodiments discussed herein.

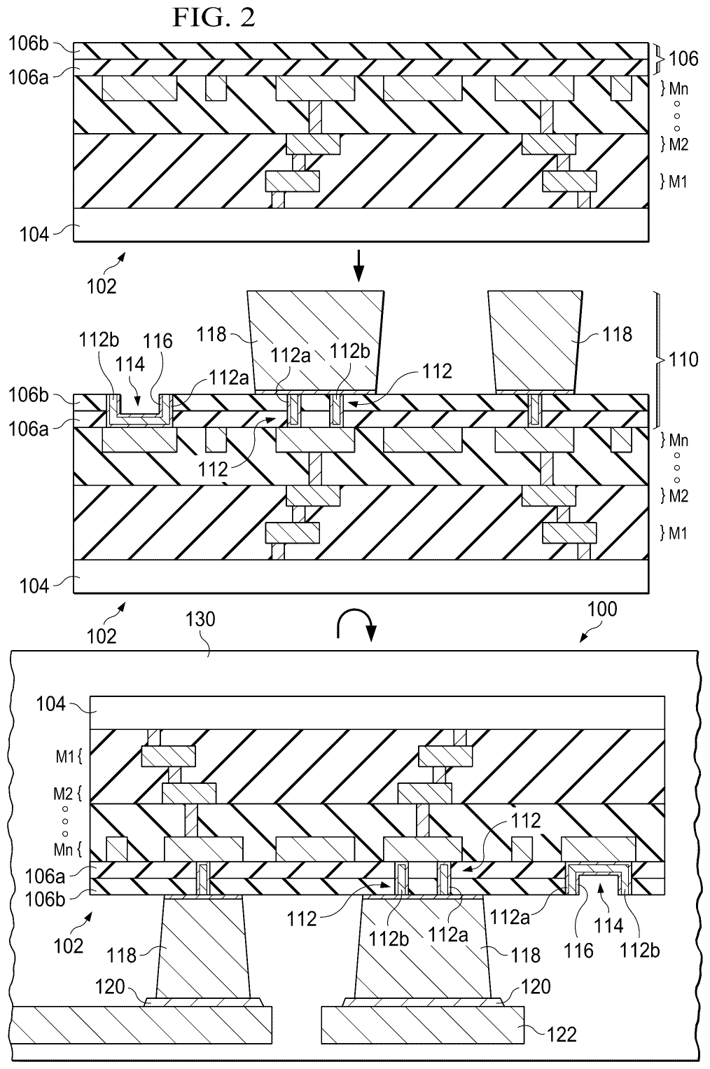

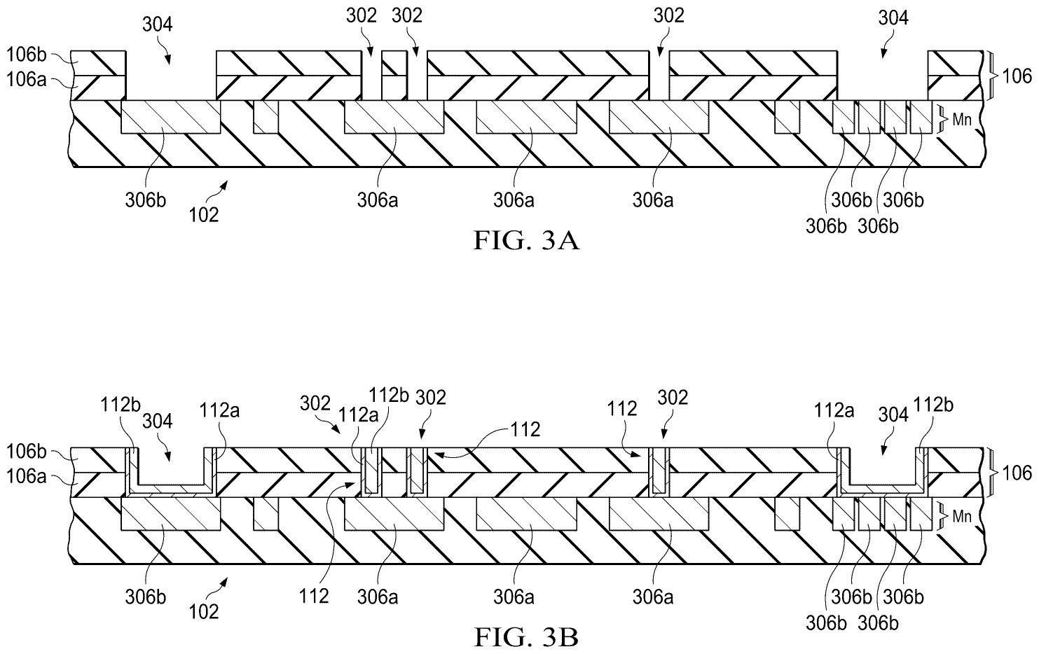

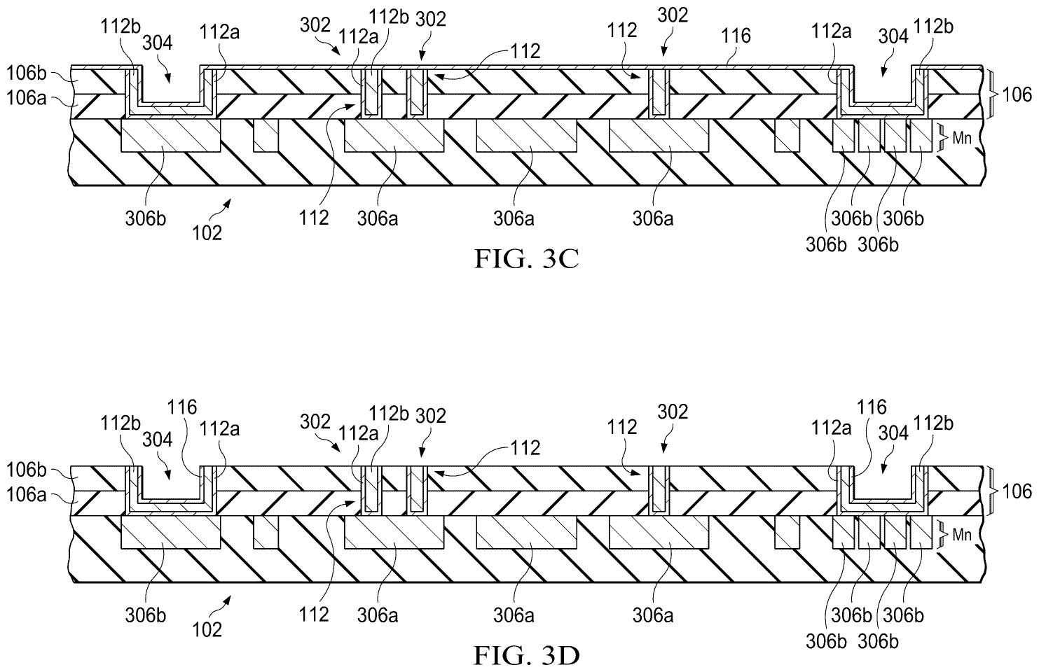

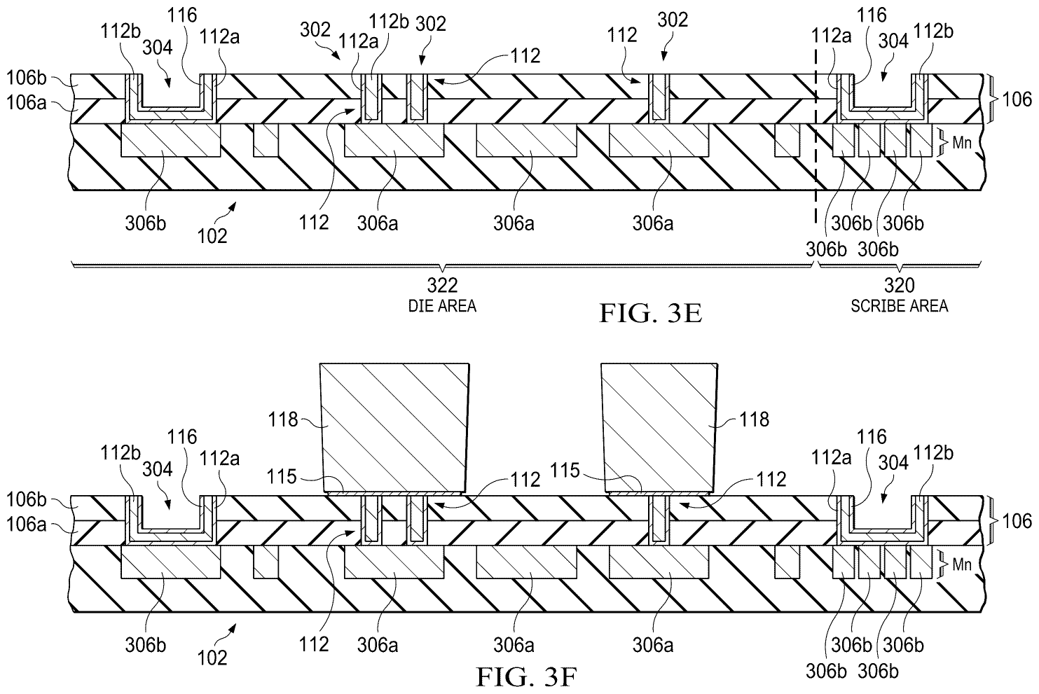

An overview of an integrated circuit device 100 according to an embodiment will now be discussed with reference to FIG. 2. Further details are discussed hereinbelow with reference to FIG. 3A-3F. An integrated circuit chip 102 is fabricated. Transistors and other devices (not shown) are formed in or on the substrate 104. A first metal interconnect level M1 is formed over the substrate. Additional metal interconnect levels M2 thru Mn are also formed. Metal interconnect level Mn comprises copper and may be formed using a copper damascene process. Metal interconnect levels M1 thru Mn-1 may comprise copper (predominantly copper) or aluminum (predominantly aluminum). Metal interconnect levels M1-Mn are used to interconnect the transistors and other devices to each other. The last metal interconnect level Mn is also used to make connections external to the chip 102. Especially in analog devices, the last metal interconnect level Mn may be thicker than the lower metal interconnect levels M1 through Mn-1. For example, Mn may have a thickness in the range of 0.2 μm to 6 μm. A passivation layer/protective overcoat 106 is formed on the last metal interconnect level Mn. As an example, passivation layer 106 may include a layer of silicon dioxide 106a and a layer of silicon nitride or silicon oxynitride 106b.

Next, chip-to-package interconnects 110 are formed. This is sometimes referred to as BUMP processing and may occur in a BUMP facility separate from the Fab. Vias 112 and probe contact areas 114 are formed through the passivation layer 106 to elements of the last metal interconnect level Mn. The vias 112 comprise a tungsten fill layer 112b. Vias 112 may also include a barrier layer 112a. The barrier layer 112a may, for example be TaN or a stack of TiN on Ti on TaN (TaN/Ti/TiN stack). Other examples include stacks of Ta/TaN, TaN/TiN, and Ta/TaN/Ti/TiN (where the materials of the stack are listed from bottom to top). The barrier layer prevents interaction between the tungsten fill 112b and the copper of metallization level Mn.

Probe contact areas 114 are used for testing and are wide enough to allow for contact by a probe of a probe card. Probe pads are typically located in a scribe area of a wafer but may also include probe contact areas such as 114 within the IC chip 102. Probe contact area 114 is significantly wider than vias 112 to allow contact by the probe. As such, the tungsten fill layer 112b does not fill probe contact area 114 as it does vias 112. Probe contact area 114 also includes probe metal stack 116 on tungsten layer 112b. Probe metal stack 116 is not located in or on vias 112. Probe metal stack 116 comprises a material that provides a structurally appropriate surface for probing. For example, probe metal stack 116 may include a palladium Pd layer on a layer of nickel Ni. Probe metal stack 116 may further include a layer of TaN or other barrier layer under the Ni layer.

A conductive copper structure 118 is formed on the vias 112 but not the probe contact areas 114. Conductive copper structure 118 may, in some cases, be referred to as bump copper. In the case of bump copper, the thickness of conductive copper structure 118 is significantly thicker than fab metal such as Mn and the conductive copper structure 118 may have a thickness in the range of 3 μm to 25 μm thick copper interconnects or 25 μm to 100 μm tall copper pillars. One or more vias 112 connect each conductive copper structure 118 to an element of the last metal interconnect level Mn.

After formation of copper structure 118, further assembly package operations are conducted. These operations may be performed in a separate assembly/test (A/T) facility. These may include placement of solder balls in WCSP processes or attachment to a lead frame or other IC device, singulation, mold, backgrind, test, tape and reel. In one example, the IC chip 102 may then attached to structure 122. The IC chip 102 may be flipped with structure 122 being leads of a lead frame. Alternatively or additionally, structures 122 may be contacts to one or more other IC chips. In addition, the means of attachment will vary depending on the packaging technology utilized. FIG. 2 illustrates a solder connection 120 between the conductive copper structure 118 and structures 122. Mold 130 is then applied to the integrated circuit chip 102, chip-to-package interconnects 110, and structures 122.

A more detailed process for forming the chip-to-package interconnects 110 with tungsten vias will now be discussed with reference to FIGS. 3A-3F. FIG. 3A shows the integrated circuit chip 102 after first openings 302 and second openings 304 have been formed through the passivation layer 106 to last metallization level Mn. Integrated circuit chip 102 has completed semiconductor fabrication, meaning the last metallization level Mn has been formed and coated with passivation layer 106. Last metallization level Mn comprises copper rather than aluminum as in prior art analog devices. Last metallization level Mn includes first elements 306a for electrical connection external to/from IC chip 102 in a final IC Device and second elements 306b for probe access during testing. Passivation layer may include a layer of silicon dioxide 106a and a layer of silicon nitride or silicon oxynitride 106b.

First openings 302 are narrower via-sized openings and second openings 304 are wider, probe pad sized openings. As an example, first openings 302 may have a width in the range of 0.1 μm to 1.5 μm and second openings 304 may have a width in the range of 8 μm to 120 μm. First openings 302 overlie/expose first elements 306a and second openings 304 overlie/expose second elements 306b.

FIG. 3B illustrates the IC chip 102 after formation of vias 112. Vias 112 may be formed by depositing a conductive barrier layer 112a over passivation layer 106 and within first openings 302 and second openings 304, such that barrier layer 112a lines the sidewalls and bottom of first openings 302 and second openings 304. Barrier layer 112a may, for example, comprise TaN. Alternatively, barrier 112a may comprise TiN on Ti on TaN on Ta. Other examples include stacks of Ta/TaN, TaN/TiN, and TaN/Ti/TiN (where the materials of the stack are listed from bottom to top). The purpose of barrier layer 112a is to block diffusion of underlying copper and allow good adhesion to tungsten which is deposited over it. Then, tungsten 112b is deposited over barrier layer 112a including in first openings 302 and second openings 304. Tungsten is deposited to a thickness that fills first openings 302 but because second openings 304 are significantly wider than first openings 302, tungsten does not fill second openings 304. As shown in FIG. 3B, tungsten 112b may, along with barrier 112a, line the sidewalls and bottom of second openings 304. Chemical-mechanical-polishing (CMP) is then performed to remove barrier layer 112a and 112b from the surface of passivation layer 106, leaving filled vias 112.

After forming filled vias 112, a probe metal/metal stack 116 is deposited over passivation layer 106 and filled vias 112, as shown in FIG. 3B. Probe metal stack 116 is also deposited in second openings 304. Because vias 112 are completely filled, the probe metal stack 116 does not extend into first openings 302. Probe metal stack 116 comprises a metal that is appropriate for probing without causing extensive wear on a probe card used for probing. One suitable example is Pd on Ni. In another suitable example, a stack of Pd on Ni on TaN. Other examples include Pd on Ni on TaN on Ta, or aluminum.

A second CMP is performed on the probe metal stack 116 to remove the probe metal stack from over the passivation layer 106 and vias 112 while leaving the probe metal stack 116 over the tungsten 112b and barrier 112a on the sidewalls and bottom of second openings 304, as shown in FIG. 3D.

Because the last metallization level Mn comprises copper rather than aluminum, several challenges are presented when it comes to probing the IC chip 102. Unlike aluminum, copper oxidizes when exposed to the ambient such as that required for probing. This is especially problematic during a data retention bake where the IC chip is probed then baked for a given time and then probed again. Thus, it is undesirable to have copper exposed during probe and/or to probe between forming the openings in the passivation layer and filling the vias. Using a tungsten plug for probing causes extensive probe card wear making its use in production undesirable. Using other materials, suitable for probing, to fill the openings over copper Mn, such as physical vapor deposition (PVD) aluminum or PVD Ni/Pd, leaves voids when filling narrow vias.

Accordingly, the embodiments disclosed herein make use of narrower and wider openings in the passivation layer to balance the competing requirements of probe and forming efficient chip-to package interconnects to provide different surfaces for the narrower first openings 302 (tungsten) and wider second openings 304 (Pd).

After the second CMP, the IC chip 102 may be probed. FIG. 3E shows a second opening 304 in the scribe area 320. Scribe areas are where the IC chip 102 is singulated or separated from other IC chips on the wafer. This is where the saw or laser passes during assembly-packaging. While various test structures may be formed in the scribe areas, the functional circuitry and associated interconnect of the IC chip is located in the die area 322. Second openings 304 may optionally also be formed in the die area 322 as shown in FIG. 3E and remain part of the finished IC device.

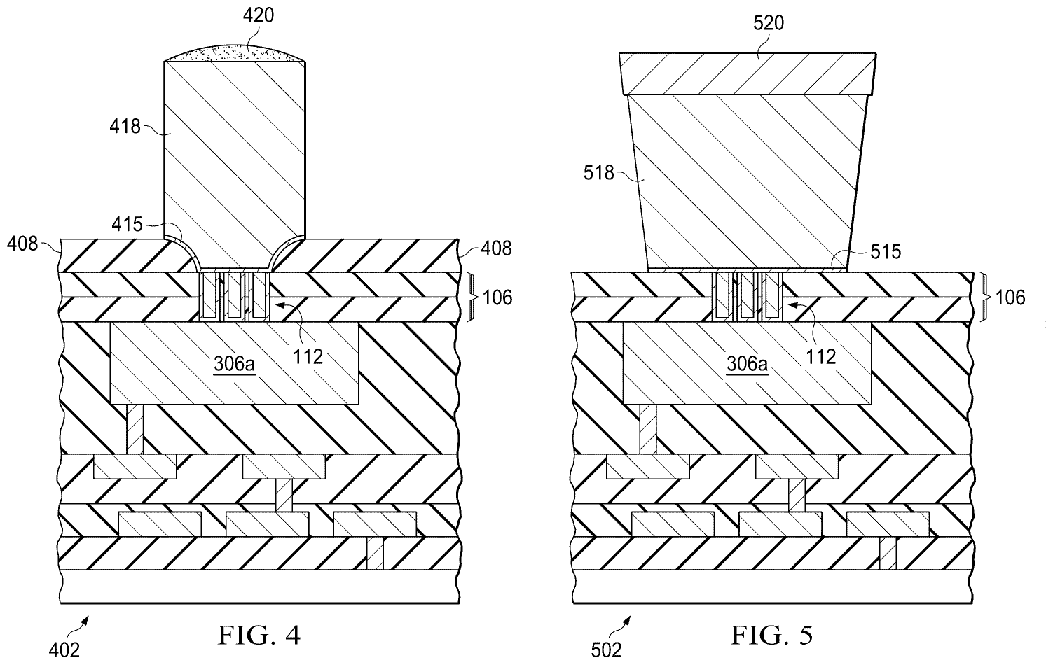

Referring to FIG. 3F, copper conductive structures 118 are formed over vias 112. A barrier layer 115 may be formed over the vias prior to forming the copper conductive structures 118. Barrier layer 115 may, for example, comprises TiW or Ti. Conductive structures 118 may be formed by forming a pattern and electroplating copper in openings in the pattern. Vias 112 electrically connect between copper conductive structures 118 and first elements 306a of last metallization level Mn. Copper conductive structures 118 may sometimes be referred to as bump copper and may take many forms as discussed below with reference to FIGS. 4 through 9.

After forming copper conductive structures 118, IC device may be completed by performing the desired assembly packaging steps on IC chip 102. Several different chip-to-package interconnects and assembly packaging options are discussed below with respect to FIGS. 4-9.

FIG. 4 illustrates IC chip 402 with bump processing in the form of a copper pillar 418 (as copper conductive structure 118 of FIG. 2). As in the other embodiments, IC chip 402 includes first element 306a and vias 112 through passivation layer 106. A protective dielectric layer 408 is formed over passivation layer 106 and vias 112. For example, protective dielectric layer 408 comprises polyimide. Other polymers such as polybenzoxazole (PBO) or bisbenzocyclobutene (BCB) may alternatively be used.

An opening is formed through protective dielectric layer 408 to expose the tops of vias 112. A barrier layer 415 is formed over the protective layer 408 including within the opening so as to contact the tops of vias 112. Barrier layer 415 may comprise TiW or Ti, for example. Bump copper processing is formed on the barrier layer 415 to form a thick copper pillar 418. Copper pillar 418 is significantly thicker than first element 306a (Mn) and may have a thickness in the range of 25 μm to 100 μm versus 0.1 μm to 6 μm for first element 306a. Adhesive 420, such as solder, is formed on the surface of copper pillar 418. The IC chip 402 is then transferred to assembly-packaging where adhesive 420 may be used to connect copper pillar 418 to leads of a lead frame or to another IC chip after singulation (similar to that discussed above relative to FIG. 2) and formation of the IC device may be completed.

FIG. 5 illustrates IC chip 502 with bump processing in the form of a copper conductive structure 518 with an overlying metal 520. Metal 520 may be referred to as a wire bond metal stack or a probe metal stack and may comprise a stack of Ni/Pd or alternatives such as Ni/Au or Ni/Pd/Au or aluminum. A barrier layer 515 is formed over the protective layer 106 so as to contact the tops of vias 112. Barrier layer 515 may comprise TiW or Ti, for example. Bump copper processing is formed on the barrier layer 515 to form a thick copper conductive structure 518. Copper structure 518 is significantly thicker than first element 306a (Mn) and may have a thickness in the range of 3 μm to 25 μm. Metal 520 (e.g., Ni/Pd) is formed on the copper structure 518. The IC chip 502 is then transferred to assembly-packaging where the IC chip 502 is wirebonded and singulated, mold compound is applied, and formation of the IC device may be completed.

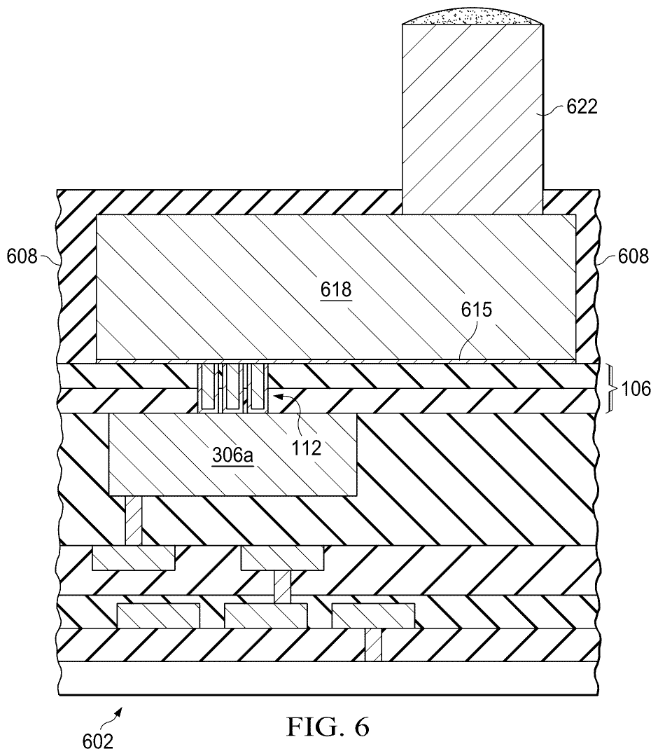

FIG. 6 illustrates IC chip 602 with bump processing in the form of a first copper conductive structure 618 and a copper post 622. A barrier layer 615 is formed over the protective layer 106 so as to contact the tops of vias 112. Barrier layer 615 may comprise TiW or Ti, for example. Copper conductive structure 618 is formed on barrier layer 615. Copper structure 618 is thicker than first element 306a (Mn) and may have a thickness in the range of 3 μm to 25 μm. Next, a protective dielectric layer 608, such as polyimide, is formed over the IC chip 602. An opening is formed in protective dielectric layer 608 and a copper post 622 is formed in the opening. The IC chip 602 may then be singulated, for example in an assembly-packaging facility. The copper post 622 is attached to a leadframe and molding is applied to the IC chip 602.

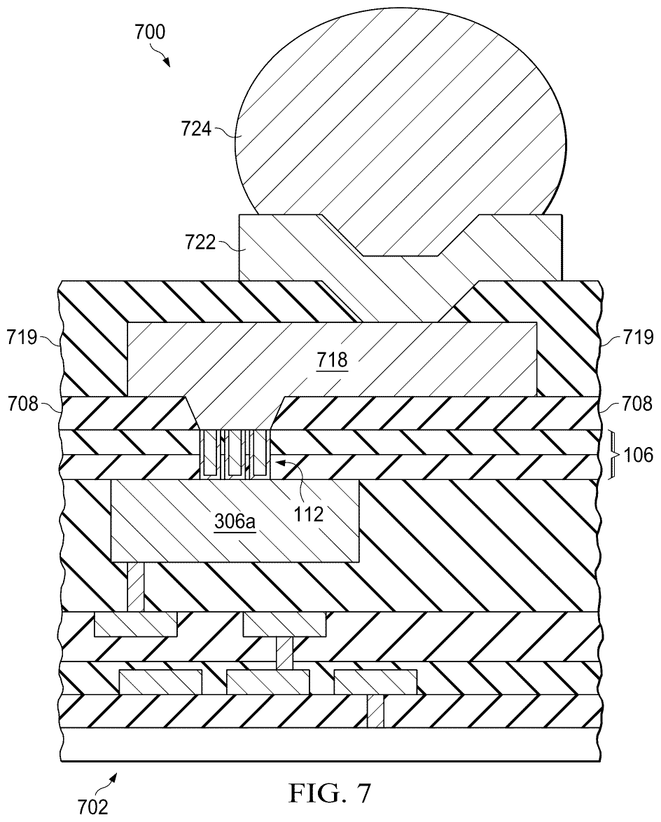

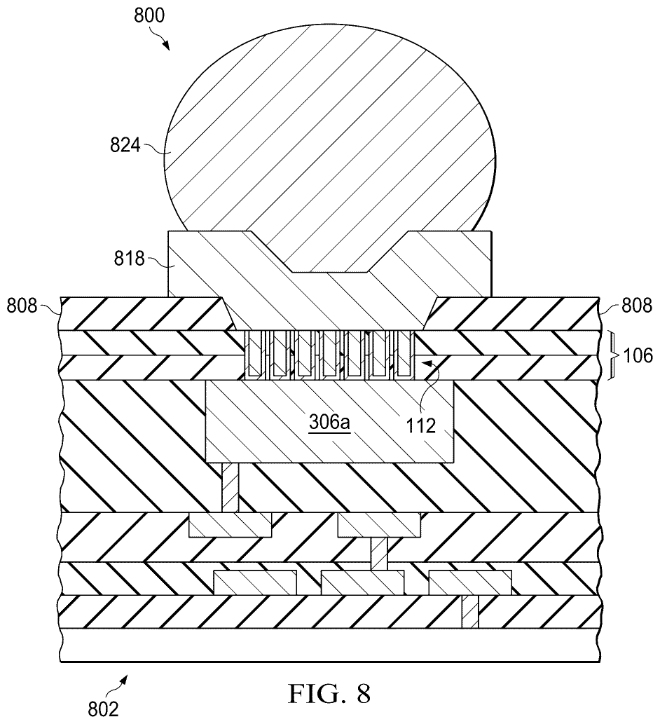

FIG. 7 illustrates IC chip 702 with further processing in the form of a copper redistribution layer 718 (as copper conductive structure 118 of FIG. 2) and an under-bump metallization (UBM) layer 722 upon which a solder ball 724 is placed. Packaging of IC device 700 may be referred to as a WCSP where the solder ball 724 is exposed for attachment of the completed IC device 700 to, for example, a printed circuit board as desired by a customer. A first, optional, protective dielectric layer 708, such a polyimide, is formed over IC chip 702. An opening is formed in protective dielectric layer 708 if present, and a copper redistribution layer (RDL) 718 is formed over the first protective dielectric layer 708 including within the opening. RDL layer 718 makes electrical contact through vias 112 to first element 306a of Mn. A second protective dielectric layer 719, such as polyimide, is formed over the copper RDL 718. An opening is formed in the second protective layer 719 and UBM layer 722 is formed over the second protective layer 719 including within the opening. The above steps may be performed in a bump facility. After placing the solder ball 724 in the opening, the IC chip 702 is singulated.

FIG. 8 illustrates another wafer chip scale type of IC device 800 where the copper conductive structure 118 takes the form of an UBM layer 818. IC chip 802 is further processed by applying a protective layer 808 such as polyimide, forming an opening in the protective layer 808 to expose the tops of vias 112, forming copper UBM layer 818 over the protective layer 808, including within the opening to contact vias 112, and forming solder ball 824 on copper UBM layer 818. UBM layer 818 makes electrical contact through vias 112 to first element 306a. After placing the solder ball 824, the IC chip 802 is singulated.

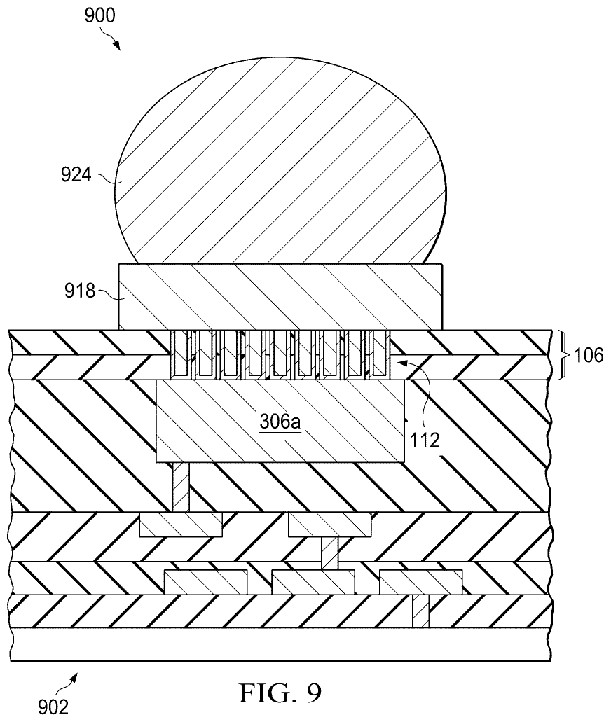

FIG. 9 illustrates another wafer chip scale type of IC device 900 where the copper conductive structure 118 takes the form of an UBM layer 818. IC chip 902 is further processed by forming copper UBM layer 918 over passivation layer 106 and forming solder ball 924 on UBM layer 918. Copper UBM layer 918 makes electrical contact through vias 112 to first element 306a. After placing the solder ball 924, the IC chip 902 is singulated.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A semiconductor die assembly, comprising:
a semiconductor die including:
an integrated circuit;
a metal layer connected to the integrated circuit; and
a passivation layer over the metal layer; and
a chip-to-package interconnect structure over the passivation layer, the chip-to-package interconnect structure including:
a via connected to an element of the metal layer through the passivation layer, the via having a barrier material at a sidewall of the via and extended across a bottom of the via, wherein a fill material fills a remaining space in the via; and
a conductive member over the passivation layer, the via coupled between the conductive member and the element of the metal layer.

2. The semiconductor die assembly of claim 1, wherein:
the semiconductor die includes a plurality of copper layers; and
the metal layer corresponds to a top copper layer of the plurality of copper layers.

3. The semiconductor die assembly of claim 1, wherein the metal layer includes copper.

4. The semiconductor die assembly of claim 1, wherein:
the barrier material includes Ti, TiN, Ta, TaN, or a combination thereof; and
the fill material includes tungsten.

5. The semiconductor die assembly of claim 1, wherein the conductive member of the chip-to-package interconnect structure includes copper.

6. The semiconductor die assembly of claim 1, wherein the conductive member is a copper pillar.

7. The semiconductor die assembly of claim 1, wherein the conductive member is a copper structure with an overlying Ni layer.

8. The semiconductor die assembly of claim 1, wherein the conductive member includes a conductive redistribution layer.

9. The semiconductor die assembly of claim 8, wherein the conductive redistribution layer includes copper.

10. The semiconductor die assembly of claim 1, wherein the conductive member includes an under-bump conductive structure.

11. The semiconductor die assembly of claim 10, wherein the under-bump conductive structure includes copper.

12. The semiconductor die assembly of claim 1, further comprising:
a probe contact area connected to the metal layer, the probe contact area including the barrier material and the fill material on the barrier material.

13. The semiconductor die assembly of claim 12, wherein the probe contact area further includes a probe metal stack on the fill material.

14. The semiconductor die assembly of claim 13, wherein the probe metal stack includes a layer of Ni.

15. The semiconductor die assembly of claim 1, further comprising:
a second barrier material disposed between the via and the conductive member.

16. The semiconductor die assembly of claim 15, wherein the second barrier material includes TiW or Ti.

17. The semiconductor die assembly of claim 1, further comprising:
a dielectric layer disposed between the via and the conductive member, the dielectric layer including an opening, wherein the via couples to the conductive member through the opening.

18. The semiconductor die assembly of claim 1, wherein the conductive member includes a redistribution layer, the semiconductor die assembly further comprising:
a polyimide layer over the redistribution layer; and
an under-bump metal structure connected to the redistribution layer through an opening in the polyimide layer.

19. The semiconductor die assembly of claim 18, further comprising:
a solder bump disposed on the under-bump metal structure.

20. The semiconductor die assembly of claim 1, wherein the via has a first width at the bottom and a second width at a top of the via, the second width substantially same as the first width.

21. A method of manufacturing a semiconductor die assembly, comprising:
forming a semiconductor die including:
an integrated circuit;
a metal layer connected to the integrated circuit; and
a passivation layer over the metal layer; and
forming a chip-to-package interconnect structure over the passivation layer by:
forming an opening through the passivation layer, the opening exposes an element of the metal layer;
depositing a barrier material over the passivation layer and into the opening, wherein the barrier material lines a sidewall of the opening and extends across a bottom of the opening;
depositing a fill material over the barrier material, the fill material filling the opening;
removing the fill material and the barrier material over the passivation layer; and
forming a conductive member over the passivation layer, the conductive member being electrically coupled to the element of the metal layer by the fill material in the opening.

22. The method of claim 21, wherein the opening is a first opening and the element is a first element of the metal layer, the method further comprising:
forming a second opening through the passivation layer, the second opening exposing a second element of the metal layer, wherein the second openings is wider than the first opening.

23. The method of claim 22, wherein the first opening and the second opening are formed concurrently.

24. The method of claim 22, wherein:
the barrier material lines a sidewall of the second opening and extends across a bottom of the second opening as a result of depositing the barrier material; and
the fill material forms on the barrier material lining the sidewall of the second opening and extending across the bottom of the second opening without filling the second opening as a result of depositing the fill material.

25. The method of claim 24, further comprising:
forming a probe metal stack over the fill material, the probe metal stack extending into the second opening but not into the first opening.

26. The method of claim 25, wherein the probe metal stack includes a layer of Ni.

27. The method of claim 25, further comprising:
probing the semiconductor die by contacting the probe metal stack in the second opening.

28. The method of claim 21, further comprising:
singulating the semiconductor die from other semiconductor dies of a wafer;
attaching the semiconductor die to a lead frame using the conductive member; and
applying a mold compound to the semiconductor die attached to the lead frame.

29. The method of claim 21, wherein:
the semiconductor die includes a plurality of copper layers; and
the metal layer corresponds to a top copper layer of the plurality of copper layers.

30. The method of claim 21, wherein the metal layer includes copper.

31. The method of claim 21, wherein:
the barrier material includes Ti, TiN, Ta, TaN, or a combination thereof; and
the fill material includes tungsten.

32. The method of claim 21, wherein the conductive member of the chip-to-package interconnect structure includes copper.

33. The method of claim 21, further comprising:
forming a second barrier material disposed between the via and the conductive member of the chip-to-package interconnect structure.

34. The method of claim 21, further comprising:
forming a dielectric layer disposed between the via and the conductive member of the chip-to-package interconnect structure, the dielectric layer including a second opening, wherein the via couples to the conductive member of the chip-to-package interconnect structure through the second opening.

35. The method of claim 21, wherein the via has a first width at the bottom and a second width at a top of the via, the second width substantially same as the first width.
